(19) United States
(12) Patent Application Publication
(10) Pub. No.: US 2024/0290391 A1
(43) Pub. Date: Aug. 29, 2024

(54) COMPLEX PAGE ACCESS IN MEMORY DEVICES

(71) Applicant: Micron Technology, Inc., Boise, ID (US)

(72) Inventors: Dmitri Yudanov, Sacramento, CA (US); Jeongsu Jeong, Boise, ID (US)

(21) Appl. No.: 18/417,899

(22) Filed: Jan. 19, 2024

Related U.S. Application Data
(60) Provisional application No. 63/487,400, filed on Feb. 28, 2023.

(51) Int. Cl. G11C 16/12

(52) U.S. Cl. CPC G11C 16/12

(57) ABSTRACT

A system for providing complex page access in memory devices, such as hybrid-bonded memory is disclosed. The system receives a plurality of requests for data, such as from a host device. The system identifies a memory page of a memory device storing data bits corresponding to the requested data. The memory page may be spread across a plurality of sections of a memory bank of the memory device. Each section of the memory bank being utilized for a portion of the memory page may be addressable by a separate row address. The system activates the memory page as a whole and enables the data to be accessed from different memory rows in different sections of the memory page of the memory device using the separate row addresses. The system accomplishes the foregoing instead of requiring access from only a single location of the memory bank at a time.

### RELATED APPLICATIONS

The present application claims priority to Prov. U.S. Pat. App. Ser. No. 63/487,400 filed Feb. 28, 2023, the entire disclosure of which application are hereby incorporated herein by reference.

### FIELD OF THE TECHNOLOGY

At least some embodiments disclosed herein relate to memory devices, memory access technologies, hybrid-bonded memory technologies, high-bandwidth memory technologies, tightly-coupled memory technologies, and more particularly, but not limited to, a system and method for facilitating complex page access in memory devices, such as hybrid-bonded memory devices.

### BACKGROUND

Typically, computing systems and devices typically include processors and memory devices, such as memory chips or integrated circuits. The memory devices may be utilized to store data that may be accessed, modified, deleted, or replaced. The memory devices may be, for example, non-volatile memory devices that retain data irrespective of whether the memory devices are powered on or off. Such non-volatile memories may include, but are not limited to, read-only memories, solid state drives, and NAND flash memories. Additionally, the memory devices may be volatile memory devices, such as, but not limited to, dynamic and/or static random-access memories, which retain stored data while powered on, but are susceptible to data loss when powered off. In response to an input, such as from a host device, the memory device of the computing system or device may retrieve stored data associated with or corresponding to the input. In certain scenarios, the data retrieved from the memory device may include instructions, which may be executed by the processors to perform various operations and/or may include data that may be utilized as inputs for the various operations. In instances where the one or more processors perform operations based on instructions from the memory device, data resulting from the performance of the operations may be subsequently stored into the memory device for future retrieval.

In order to access data stored in a memory device, a host device may transmit a request for data stored in the memory device. A row address specified in the request may be sent to a memory bank and the memory page containing the row of the memory bank may be activated, such as by utilizing activate command. The data bits contained in the row may be sensed by sense amplifiers and the values of the data bits may be error corrected, inverted, and/or otherwise processed prior to providing the values to the requesting host device. However, if the host device is requesting data stored in other rows of the memory bank, the memory device needs to first close the activated memory page and then issue a new activate command to activate the other memory page containing the rows storing the requested data. Such a process consumes excess memory resources over time and contributes to wear and tear of the memory device. As a result, currently technologies may be enhanced to reduce memory resource usage, enhance memory access efficiency, provide greater memory device versatility, and provide a plurality of other benefits.

### BRIEF DESCRIPTION OF THE DRAWINGS

The embodiments are illustrated by way of example and not limitation in the figures of the accompanying drawings in which like references indicate similar elements.

FIG. 1 illustrates an exemplary system including a memory device and host device facilitating complex page access in the memory device according to embodiments of the present disclosure.

FIG. 2 illustrates an exemplary memory device including memory banks and sections enabling complex page access in the memory device according to embodiments of the present disclosure.

FIG. 3 illustrates an exemplary timing diagram illustrating activation of a memory page according to embodiments of the present disclosure.

FIG. 4 illustrates an exemplary timing diagram illustrating activation of a memory page according to enhanced embodiments of the present disclosure.

FIG. 5 illustrates an exemplary timing diagram illustrating write and read commands issued during complex page access in a memory device according to embodiments of the present disclosure.

FIG. 6 illustrates an exemplary method facilitating complex page access in memory devices, such as hybrid-bonded memory devices, in accordance with embodiments of the present disclosure.

FIG. 7 illustrates a schematic diagram of a machine in the form of a computer system within which a set of instructions, when executed, may cause the machine to facilitate complex page access in memory devices according to embodiments of the present disclosure.

### DETAILED DESCRIPTION

The following disclosure describes various embodiments for a system 100, memory devices 102, and accompanying methods for facilitating complex page access in memory devices, such as, but not limited to, hybrid-bonded memory devices, high bandwidth memory devices, tightly-coupled memory devices, among other types of memory devices. In particular, the functionality provided by system 100 and methods enable memory page access using fewer computing resources, while providing greater efficiency, greater convenience, and enhanced memory access versatility than existing memory access technologies. In certain embodiments of hybrid-bonded memory devices, a memory page may be spread across many sections of a memory bank. For example, an 8 KB memory page may be spread among or across eight sections of a memory bank. In certain embodiments, a row address may be sent to all sections of a memory bank and the memory row may be sensed by sense amplifiers. In such a scenario, the memory hardware may be relatively simple and amortized over a large number of bit lines (i.e., columns or column lines). However, in certain situations, such an implementation may not be optimal because data requested by a host device comes from the same location in each section of the memory bank. In an exemplary scenario, if an application of a host device (e.g., host device 170) needs to access a 1 KB piece of data from another row of a particular section of the memory bank, then the memory hardware would need to close the current memory page and open another memory page containing the other row.

Notably, however, embodiments of the system 100, memory devices 102, and methods of the present disclosure enable the memory hardware to accept a different address for each section of a memory page. In certain embodiments, for example, memory devices may be modified to enable accessing of pieces or sections of a larger memory page from different rows located in different sections of a memory bank of a memory device. In certain embodiments, the entire memory page may be activated by a controller of the memory device, however, the data may be obtained from different memory rows in each section of the memory page. In certain embodiments, the controller of the memory device may disable certain sections of the memory page to save power and other memory resources. For example, if requested data is known not to be located in certain sections of the memory page, such sections may remain in a deactivated state, while other sections of the memory page containing the requested data may be activated. In certain embodiments, the controller of the memory device may also be configured to handle and orchestrate scheduling scenarios for optimal memory access using the functionality provided by the system 100, memory devices 102, and methods disclosed herein.

In certain embodiments, a system for providing and/or facilitating complex page access in memory devices is disclosed. In certain embodiments, the system may include a host device and a memory device. In certain embodiments, the memory device may include a controller configured to perform various operations of the system. In certain embodiments, the controller may be configured to receive a request for data stored in the memory device, such as from the host device. In certain embodiments, the controller may be configured to activate a memory page of the memory device storing the data associated with the request. In certain embodiments, the memory page may be spread across a plurality of sections of a memory bank of the memory device. In certain embodiments, each section of the plurality of sections of may be configured to be accessible via a separate memory address of a plurality of memory addresses. In certain embodiments, the controller may be configured to facilitate access to portions of the data stored across the plurality of sections of the memory bank via the separate memory addresses for each section containing the portions of the data.

In certain embodiments, the controller of the memory device of the system may also be configured to latch the separate memory addresses for each section of the plurality of sections of the memory page after activation of the memory page. In certain embodiments, the controller may be further configured to latch the separate memory addresses for each section of the plurality of sections within a time budget, such as a time budget based on a clock frequency of the memory device. In certain embodiments, the controller may be further configured to latch the separate memory address for each section of the plurality of sections until issuance of a precharge command for closing the memory page. In certain embodiments, the controller may be further configured to write back the data latched by the memory device to the sections of the memory bank after issuance of the precharge command. In certain embodiments, the controller may be further configured to utilize cancellation logic to utilize a same row address (e.g., a first row address) of the plurality of memory addresses for all sections of the memory bank to access the data. In certain embodiments, the controller may be further configured to utilize a strobe, a keyword, or a combination thereof, to facilitate the cancellation logic. In certain embodiments, the controller may be further configured to disable at least one section of the memory page to save power associated with the memory device.

In certain embodiments, the controller may be further configured to track which columns of the memory page belong to which section of the plurality of sections to schedule column accesses for the data, such as by the host device. In certain embodiments, the controller may be further configured to generate a programmable address map to facilitate spreading of the data among the sections, a plurality of memory banks including the memory bank, or a combination thereof. In certain embodiments, the controller may be further configured to receive additional requests for the data stored in the memory device. In certain embodiments, the controller may be configured to coalesce a portion of the additional requests with the original request belonging to a same linear row of the memory page to create a set of coalesced requests. In certain embodiments, the controller may be further configured to issue a reduced activate command (e.g., a command to activate certain sections or a section of the memory page) for accesses associated with the set of coalesced requests that are spatially local in the memory page. In certain embodiments, the controller may be further configured to generate a priority queue including a plurality of requests including the request. In certain embodiments, the plurality of requests may be scheduled based on a priority associated with each request of the plurality of requests, an age of each request of the plurality of requests, any other characteristic of feature, or a combination thereof. In certain embodiments, the controller may be configured to compose the memory page based on the priority queue.

In certain embodiments, a memory device for facilitating and/or providing complex page access for memory devices, such as hybrid-bonding memory devices is provided. In certain embodiments, the memory device may be configured to include a plurality of memory banks, each containing any number of sections that are separately addressable so that different rows of different sections of a memory page spread across the sections of the memory bank may be accessed while the memory page is open. In certain embodiments, the memory device may include a controller that may be configured to generate a priority queue for a plurality of requests for data stored in the memory device. In certain embodiments, the priority queue may be generated based on an order of receipt of each request of the plurality of requests, an age of each request of the plurality of requests, other criteria, or a combination thereof. In certain embodiments, the controller may be configured to identify a memory page of the memory device storing the data for a portion of the plurality of requests.

In certain embodiments, the controller may be configured to issue an activate command to activate the memory page storing the data for the portion of the plurality of requests. In certain embodiments, the memory page may be spread across a plurality of sections of a memory bank of the memory device and each section of the plurality of sections may be made accessible via a separate memory address of a plurality of memory addresses. In certain embodiments, the controller may be configured to enable access to portions of the data stored across the plurality of sections of the memory bank via the separate memory address for each section containing the portions of the data. In certain embodiments, the controller may be further configured to adjust a test clock frequency of the memory device to increase a bandwidth associated with the plurality of memory addresses. In certain embodiments, the controller may be further configured to close the memory page after the portions of the data stored across the plurality of sections of the memory bank are accessed, such as by the host device. In certain embodiments, the controller may be further configured to enable access to the portions of the data from different rows in the plurality of sections of the memory bank.

In certain embodiments, a method for providing and/or facilitating complex page access in memory devices is provided. In certain embodiments, the method may include generating, at a memory device, a programmable address map to spread a memory page across a plurality of sections of a memory bank of the memory device. In certain embodiments, each of the plurality of sections may be configured to have a separate memory address that may be stored in the programmable address map. In certain embodiments, the method may include receiving, at the memory device, a plurality of requests for data. In certain embodiments, the method may include activating a portion of the plurality of sections of the memory bank containing data in response to the plurality of requests while maintaining deactivation of a remaining portion of the plurality of sections of the memory bank not containing the data. In certain embodiments, the method may include enabling, using the programmable address map, access to the data residing in different memory rows within the portion of the plurality of sections that have been activated.

In certain embodiments, the programmable address map may allow the spreading of data among memory banks and sections (e.g., memory tiles). In certain embodiments, memory tiles belonging to the same bank can be viewed as a bank group. In certain embodiments, a memory interface of the memory device may be configured to provide the memory controller with flexibility and capability to compose a complex page and issue an activate command to activate the memory page for random memory accesses, such as by the host device. In certain embodiments, the method may include having the controller coalesce (or combine or group) memory requests belonging to the same linear row of the memory bank and/or section of a memory bank and issue a reduced activate command for memory accesses for data that are spatially local (e.g., in the same section or sections in proximity and/or adjacent to each other). In certain embodiments, the method may include having the controller maintain a priority queue in which requests (e.g., from a host device; e.g., 64B cacheline requests) may be scheduled in the order of priority, age, and/or other characteristics. In certain embodiments, aged low priority requests may become high priority based on a threshold of time passing, gradually as time progresses, based on the host device and/or memory device changing the priority, based on any desired criteria, or a combination thereof.

In certain embodiments, features of the complex memory page formation may allow the controller to satisfy priority requirements in a superior fashion when compared to existing technologies for random accesses. In certain embodiments, the method may include having the controller compose complex memory pages straight out of a queue with potential speedup of up to orders of magnitude (e.g., 8×) compared to existing technologies. In certain embodiments, the method may include latching the memory page in a page buffer that is shared across the plurality of sections of the memory bank. In certain embodiments, the method may also include any of the operative functionality described in the present disclosure and may be modified based on desired implementations and/or functionality. Based on the foregoing and the remaining description, the embodiments of the system 100, the memory device 102, and methods described herein are able to effectively enable complex memory page access via different rows in different sections of a memory page spread across sections of a memory bank of a memory device. Furthermore, in certain embodiments, the functionality provided by the embodiments may also require fewer memory and other computing resources, while also ensuring more efficient accessing of data stored in memory devices, such as by host devices.

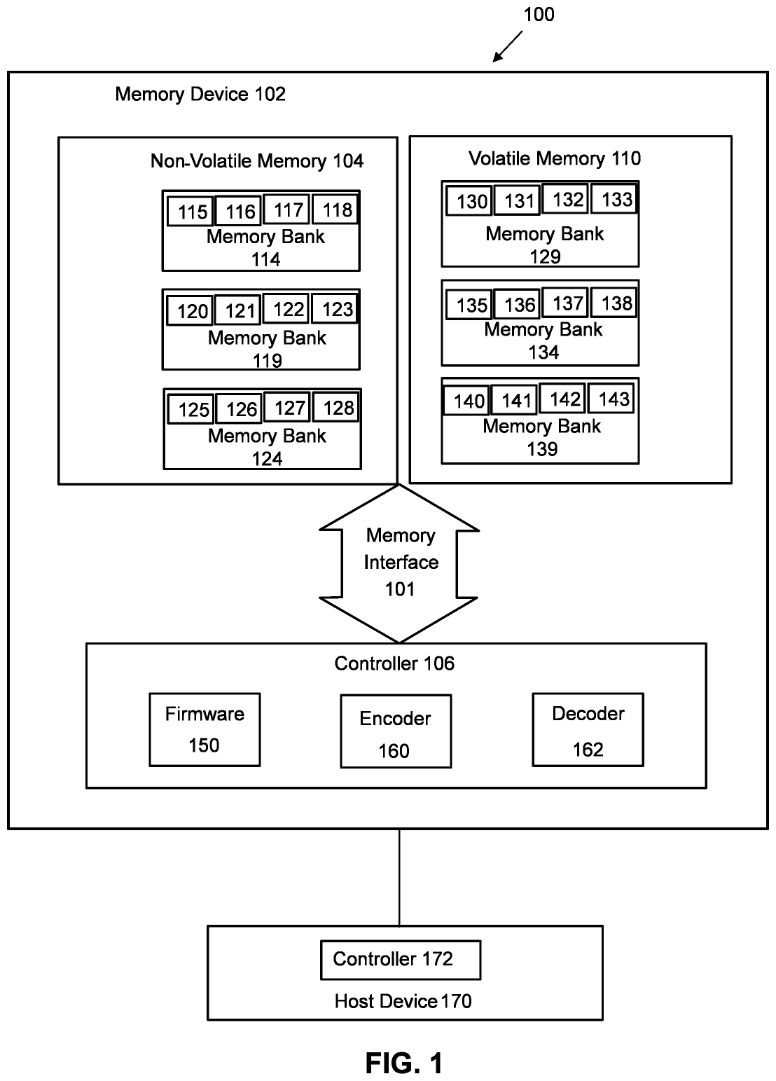

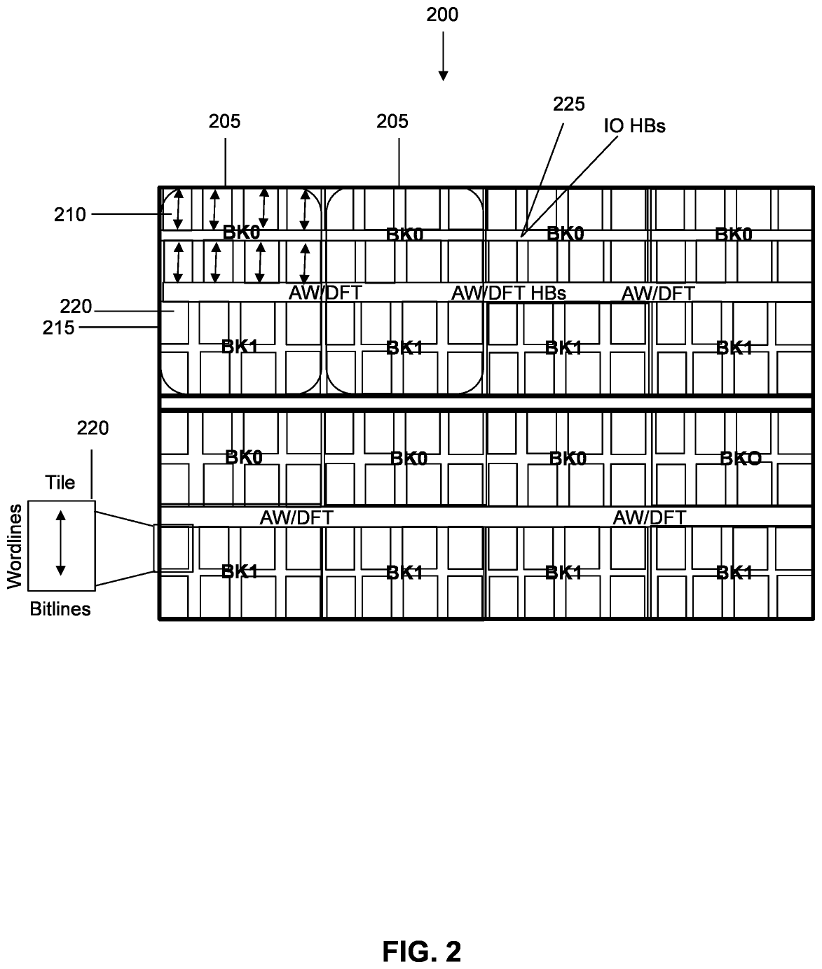

As shown in FIG. 1 and referring also to FIGS. 2-7, a system 100, a memory device 102, a host device 170, and an accompanying method 600 for providing complex page access in memory devices, such as hybrid-bonded memory devices, is provided. In FIG. 1, the system 100 may include a memory device 102, a host device 170, any other devices, or a combination thereof. In certain embodiments, the memory device 102 and other componentry illustrated in the Figures may belong to the system 100, other systems, or a combination thereof. In certain embodiments, the memory device 102 is, for example, but not limited to, a tightly-coupled random access memory, a high-bandwidth memory, a dynamic random access memory (DRAM), an SSD, eMMC, memory card, or other storage device, or a NAND-based flash memory chip or module that is capable of encoding and decoding stored data, such as by utilizing an encoder 160 and decoder 162 of the memory device 102. In certain embodiments, the memory device 102 may include any amount of componentry to facilitate the operation of the memory device 102. In certain embodiments, for example, the memory device 102 may include, but is not limited to including, a non-volatile memory 104, memory banks 114, 119, 124, a volatile memory 110, memory banks 129, 134, 139, a memory interface 101, a controller 106 (which, in certain embodiments, may include the encoder 160, a decoder 162, firmware 150, and/or other componentry), any other componentry, or a combination thereof. The memory device 102 may communicatively link with a host device 170, which may be or include a computer, server, processor, autonomous vehicle, any other computing device or system, or a combination thereof. In certain embodiments, the host device 170 may include a controller 172, which may be configured to control the operative functions of the host device 170, issue commands for the memory device 102, request data from the memory device 102, receive data from the memory device 102, modify data stored in the memory device 102, erase data on the memory device 102, perform other actions with respect to the memory device 102, or a combination thereof.

In certain embodiments, the non-volatile memory 104 may be configured to retain stored data irrespective of whether there is power delivered to the non-volatile memory 104. In certain embodiments, the non-volatile memory 104 may be configured to include any number of memory banks 114, 119, 124 that may be configured to store user data, any other type of data, or a combination thereof. In certain embodiments, the memory banks 114, 119, 124 may be activated and opened, such as upon receipt of an activate command from the host device 170, the controller 106, and/or other device. In certain embodiments, the memory banks 114, 119, 124 may be closed, such as upon receipt of a precharge command from the host device 170, the controller 106, or other device. In certain embodiments, the memory banks 114, 119, 124 of the non-volatile memory 104 may be configured to include a plurality of physical memory cells configured to store data. In certain embodiments, the non-volatile memory 104 may include a physical memory array including an array of bit cells, each of which may be configured to store a bit of data. In certain embodiments, each bit cell may be connected to a wordline (e.g., row) and bitline (e.g., column). In certain embodiments, the memory cells of the non-volatile memory 104 may be etched onto the silicon wafer forming the base of the non-volatile memory 104. The memory cells may be etched in an array of columns (e.g., bitlines) and rows (e.g., wordlines). In certain embodiments, the intersection of a particular bitline with a wordline may serve as the address of the memory cell. In certain embodiments, for each combination of address bits, the memory device 102 may be configured to assert a wordline that activates the bit cells in a particular row of a memory bank 114, 119, 124. For example, in certain embodiments, when the wordline is high, the store bit may be configured to transfer to or from the bitline. On the other hand, in certain embodiments, when the wordline is not high, the bitline may be disconnected from the cell.

In certain embodiments, the memory banks 114, 119, 124 may include sense amplifiers, which may be configured to sense charges from the memory banks 114, 119, 124 and amplify the voltage to enable the host device 170 to interpret the data stored in a particular memory bank 114, 119, 124. In certain embodiments, for example, the charges containing the data may be provided to the sense amplifiers upon receipt of an activate command, such as by the host device 170 and/or controller 106. In certain embodiments, each memory bank 114, 119, 124 may include any number of sections 115, 116, 117, 118, 120, 121, 122, 123, 125, 126, 127, 128 (or memory tiles). In certain embodiments of the present disclosure, a memory page may be spread across any number of the sections (i.e., tiles) 115-118, 120-123, 125-128 of the memory banks 114, 119, 124. In certain embodiments, the memory page may be spread across sections within a single memory bank 114, 119, 124, however, in certain embodiments, the memory page may be spread across sections within a memory bank 114, 119, 124, but also across sections of other memory banks 114, 119, 124. In certain embodiments, the sections 115-118, 120-123, 126-128 may serve as smaller pages or subpages within a larger memory page. In certain embodiments, each of the sections 115-118, 120-123, 126-128 within the larger memory page may be separately addressable with a separate row address that may be activated and/or accessed by a host device 170, the controller 106, other devices, or a combination thereof.

In certain embodiments, the volatile memory 110 may also be configured to retain stored data, however, in certain embodiments, may not retain the data after power is no longer provided to the volatile memory 110 or to the memory device 102. In certain embodiments, the volatile memory 110 may include a plurality of memory banks 129, 134, 139, which may be similarly activated and opened, such as upon receipt by the memory device 102 of an activate command. In certain embodiments, the memory banks 129, 134, 139 may include any of the componentry and/or functionality as for the memory banks 114, 119, 124. For example, the volatile memory 110 may include a physical memory array including an array of bit cells configured to store data. Bit cells in a particular row of a memory bank 129, 134, 139 may be activated in response to receipt of an activate command, such as issued by a host device 170. In certain embodiments, the memory banks 129, 134, 139 may include sense amplifiers, which may be configured to sense charges from the memory banks 129, 134, 139 and amplify the voltage to enable the host device 170 to interpret the data stored in a particular memory bank 129, 134, 139. In certain embodiments, each memory bank 129, 134, 139 may include any number of sections 130, 131, 132, 133, 135, 136, 137, 138, 140, 141, 142, 143 (or memory tiles). In certain embodiments of the present disclosure, a memory page may be spread across any number of the sections (i.e., tiles) 130-133, 135-138, 140-143 of the memory banks 129, 134, 139. In certain embodiments, a memory page may be spread across sections within a single memory bank 129, 134, 139, however, in certain embodiments, the memory page may be spread across sections within a memory bank 129, 134, 139, but also across sections of other memory banks 129, 134, 139. In certain embodiments, the sections 130-133, 135-138, 140-143 may serve as smaller pages or subpages within a larger memory page. In certain embodiments, each of the sections 115-118, 120-123, 126-128 within the larger memory page may be separately addressable with a separate row address that may be activated and/or accessed by a host device 170, the controller 106, other devices, or a combination thereof.

In certain embodiments, the controller 106 of the memory device 102 may be configured to control access to the non-volatile memory 104, the volatile memory 110, any other componentry of the memory device 102, or a combination thereof. In certain embodiments, data may be provided by controller 106 to the non-volatile memory 104, the volatile memory 110, or a combination thereof, such as by utilizing memory interface 101. For example, the data may be obtained from the host device 170 to be stored in the non-volatile memory 104, such as in a memory bank 114, 119, 124. In certain embodiments, the controller 106 may include an encoder 160 for generating ECC data (e.g., such as when writing data to the non-volatile memory 104), and a decoder 162 for decoding ECC data (e.g., when reading data, such as from the non-volatile memory 104). In certain embodiments, the controller 106 may include firmware 150, which may be configured to control the components of the system 100. In certain embodiments, the firmware 150 may be configured to control access to the non-volatile memory 104, the volatile memory 110, or a combination thereof, by the host device 170 and control the operative functionality of the memory device 102. Further details relating to the firmware 150 are discussed below. In certain embodiments, the controller 106 may include or be communicatively linked to the host device 170 and/or to the controller 172 of the host device 170, and/or other devices.

As described herein, the memory device 102 may be configured to receive data (e.g., user data) to be stored from host device 170 (e.g., over a serial communications interface and/or a wireless communications interface). In certain embodiments, the user data may be video data from a device of a user, sensor data from one or more sensors of an autonomous or other vehicle, text data, audio data, virtual reality data, augmented reality data, information, content, any type of data, or a combination thereof. In certain embodiments, memory device 102 may be configured to store the received data in memory cells of non-volatile memory 104, the volatile memory 110, or a combination thereof. In certain embodiments, the memory cells may be provided by one or more non-volatile memory chips, volatile memory chips, or a combination thereof. In certain embodiments, the memory chips may be tightly-coupled random access memories, high-bandwidth memories, hybrid-bonded memories, NAND-based flash memory chips, however, any type of memory chips or combination of memory chips may also be utilized. In certain embodiments, the memory device 102 may be configured to store received data in volatile memory 110 (which may be any type of volatile memory) on a non-persistent basis. In certain embodiments, the volatile memory 110 may include componentry, such, as but not limited to, a physical memory array.

In certain embodiments the firmware 150 of the memory device 102 may be configured to control the operative functionality of the memory device 102. In certain embodiments, the firmware 150 may be configured to manage all operations conducted by the controller 106. In certain embodiments, the firmware 150 may be configured to activate a physical row in the memory banks 114, 119, 124, the memory banks 129, 134, 139, or a combination thereof, such as in response to receipt of an activate command by the host device 170 and/or memory controller 106. In certain embodiments, the firmware 150 may be configured to deactivate or close a physical row in the memory banks 114, 119, 124, the memory banks 129, 134, 139, such as if a precharge command is received from the host device 170, a precharge command is issued by the memory device 102 itself, or a combination thereof. In certain embodiments, the activate command may be a reduced activate command that is configured to activate only certain sections or tiles of the memory banks 114, 119, 124, 129, 134, 139, such as to save on power or memory resources.

As indicated herein, in certain embodiments, the memory device 102 may be a high-bandwidth memory, tightly-coupled random access memory, and/or hybrid-bonded memory. In certain embodiments, the memory device 102 may include various componentry to support the functionality of the memory device 102. In certain embodiments, the memory device 102 may include, but is not limited to including, a plurality of memory die that when stacked on top of each other form a stacked memory die, an interface layer (e.g., interface 101 or other interface), an application specific integrated circuit physical interface layer, routing layers, through-silicon vias, an application specific integrated circuit, a package substrate, and/or bumps (or solder balls). In certain embodiments, the stacked memory die may include any number of memory die. In certain embodiments, the memory die may be any type of memory die including, but not limited to, non-volatile memory die, such as random access memory. In certain embodiments, the memory die may be connected to each other within the stack by utilizing any number of bumps (e.g., micro bumps, solder balls, etc.). Any suitable bump pitches (e.g., distance between bumps may be 6 μm) may be utilized for the bumps and any suitable bump locations may be utilized as well, such as to ensure compatibility with an application specific integrated circuit. In certain embodiments, the bumps 503 form a dense bump grid within the stacked memory die, such as in a tightly-coupled random access memory implementation.

In certain embodiments, such as the embodiments utilizing hybrid bonding, instead of using bumps to connect the dies and/or other componentry of memory device together, interconnects or other types of connections may be utilized to directly connect the componentry to each other. For example, the connections may be copper-to-copper connections. In such a scenario, such connections may provide superior interconnect density and may provide a permanent bond that combines a dielectric bond (e.g., SiOx) with metal (e.g., copper) to form interactions between the componentry. In certain embodiments, such as hybrid bonding embodiments, the hybrid bonding may be utilized to vertically connect memory dies to the wafer and/or wafers to wafers via metal pads (e.g., copper pads). In certain embodiments, the memory chip can be connected directly to a portion of a logic wafer via heterogeneous direct bonding, also known as hybrid bonding or copper hybrid bonding. In certain embodiments, direct bonding may be a type of chemical bond between two surfaces of material meeting various requirements. In certain embodiments, direct bonding of wafers may include pre-processing wafers, pre-bonding the wafers at room temperature, and annealing at elevated temperatures. For example, direct bonding can be used to join two wafers of a same material (e.g., silicon); anodic bonding can be used to join two wafers of different materials (e.g., silicon and borosilicate glass); eutectic bonding can be used to form a bonding layer of eutectic alloy based on silicon combining with metal to form a eutectic alloy.

Hybrid bonding can be used to join two surfaces having metal and dielectric material to form a dielectric bond with an embedded metal interconnect from the two surfaces. The hybrid bonding can be based on adhesives, direct bonding of a same dielectric material, anodic bonding of different dielectric materials, eutectic bonding, thermocompression bonding of materials, or other techniques, or any combination thereof. As indicated in the present disclosure, copper microbump may be a technique to connect dies at packaging level. In such embodiments, small metal bumps can be formed on dies as microbumps and connected for assembling into an integrated circuit package. It may be difficult to use microbumps for high density connections at a small pitch (e.g., 10 micrometers). To that end, hybrid bonding can be used to implement connections at such a small pitch not feasible via microbumps. In certain embodiments, the integrated circuit die for the memory device 102 may include a memory cell array having a bottom surface; and the integrated circuit die having the inference logic circuit (e.g., portion with the controller 106) may have a portion of a top surface. The two surfaces can be connected via hybrid bonding to provide a portion of a direct bond interconnect between the metal portions on the surfaces.

In certain embodiments, the memory device 102 may include an interface layer that may be configured to serve as an intermediary layer between the stacked memory die and an application specific integrated circuit. In certain embodiments, connections and circuits (e.g., input output circuits) that may normally reside within the stacked memory die, the application specific integrated circuit, or both, may be migrated into and configured to reside or coalesce within the interface layer. In certain embodiments, the interface layer may further include any number of routing layers. In certain embodiments, the routing layers may be configured to facilitate routing of signals between the stacked memory die and an application specific integrated circuit. In certain embodiments, the routing layers may be connected to through-silicon vias connected to the stacked memory die and to through-silicon vias extending into the application specific integrated circuit and connected to a tightly-coupled random access memory physical interface layer of the application specific integrated circuit. In certain embodiments, the interface layer may include any number of through-silicon vias that may extend through the height of the interface layer and may be configured to enable communication through the stacked memory die.

Referring now also to FIG. 2, an exemplary memory device 200 including memory banks and sections enabling complex page access in the memory device is shown. In certain embodiments, the memory device 200 may incorporate any of the functionality of memory device 102 and may be a hybrid-bonded memory device, tightly-coupled memory device, high-bandwidth memory device, or a combination thereof. In certain embodiments, the exemplary memory device 200 may include a plurality of memory banks (e.g., BK0 205, BK1 215, etc.), input-output interfaces (e.g., for high-bandwidth capability), any number of channels (e.g., Ch A/B, Ch C/D, etc.), and/or any number of other componentry. Each of the memory banks 205, 215 may include any number of sections or tiles 210, 220. In certain embodiments, for example, each bank may include eight sections, as shown in FIG. 2, and, in certain embodiments, the memory banks 205, 215 may be directly connected to each other. For example, in certain implementations, such as in hybrid-bonded solutions, a memory page may be spread across many sections 210, 220 of a bank 205, 215 (e.g., 8 KB page is spread among 8 sections 210, 220). In certain embodiments, each section 210, 220 may include any number of wordlines (e.g., rows) and bitlines (e.g., columns. In certain embodiments, each section 210, 220 of each memory bank 205, 215 may be separately addressable and a memory page of the memory device 200 may spread across any number of sections 210, 220 and/or memory banks 205, 215. In certain embodiments, if a host device 170 issues requests for data including a plurality of row addresses, the memory device 200 may determine that the plurality of row addresses belong to the same memory page, but in different sections 210, 220. In certain embodiments, the memory page as a whole may be activated, however, the data can come from different memory rows in each section 210, 220, or activation (e.g., using a reduced activate command) to some sections 210, 220 may be disabled to save on power (e.g., sections not included requested data or sections that have data that can be retrieved after data from other sections 210, 220 is obtained). In certain embodiments, different rows in the different sections 210, 220 may be activated simultaneously to allow for obtaining of data from the different rows in the different sections instead of having to retrieve a portion of the data from one row and then closing the memory page and then activating another row to obtain another portion of the data.

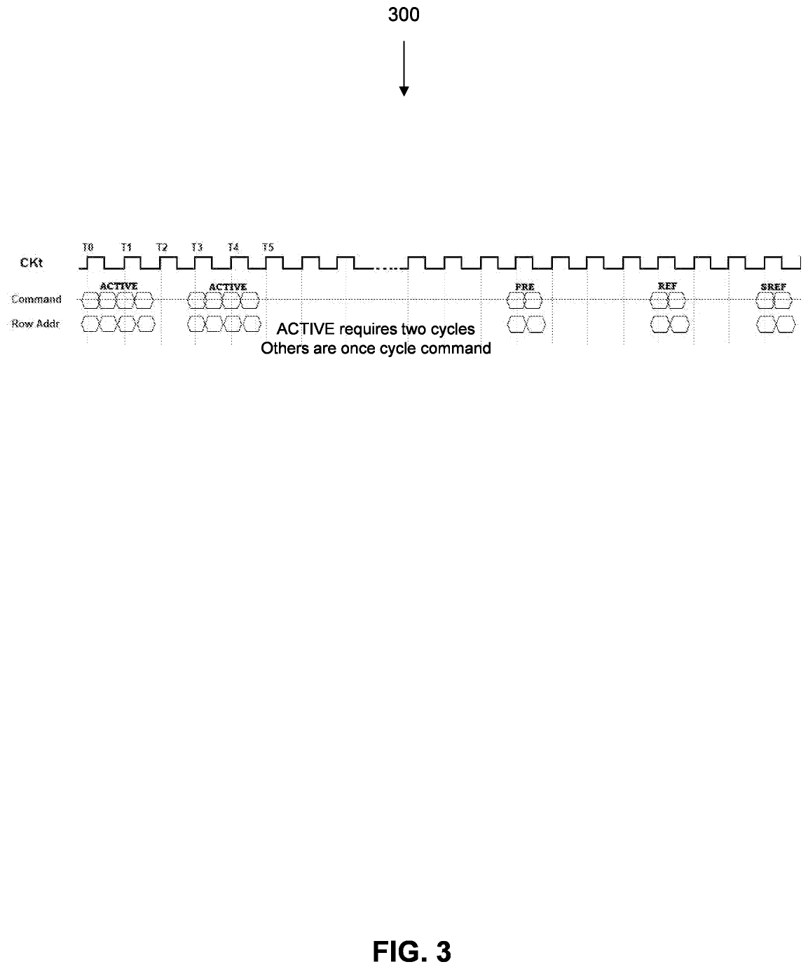

Referring now also to FIG. 3, an exemplary timing diagram 300 illustrating activation of a memory page according to embodiments of the present disclosure is shown. In certain embodiments, timing diagram 300 may illustrate various signals and commands for a hybrid-bonded memory device. In certain embodiments of timing diagram 300, a row address may be sent to a bank 205, 215 (e.g., all sections) and a row may be sensed by sense amplifiers (i.e., activated). This may allow the memory hardware to be simple and the hardware may be amortized over a large number of bitlines (i.e., columns). However, in certain scenarios, such an implementation may not be optimal because data comes from the same location (e.g., row) in each tile. As a result, if an application needs to access a 1 KB piece of data from another row of a particular section 210, 220 then the memory device 200 (or memory device 102) would need to close the current memory page and open another memory page. In FIG. 3, an exemplary test clock (CKT/TCK) frequency signal is shown, issuance of a activate command to activate a memory page is shown, issuance of a precharge command to close out a memory page is shown, along with activity from the logic portion of the memory and the physical memory portion of the memory. In certain embodiments, for example, an activate may require two cycles and other commands may be one cycle commands (e.g. precharge), as shown in FIG. 3.

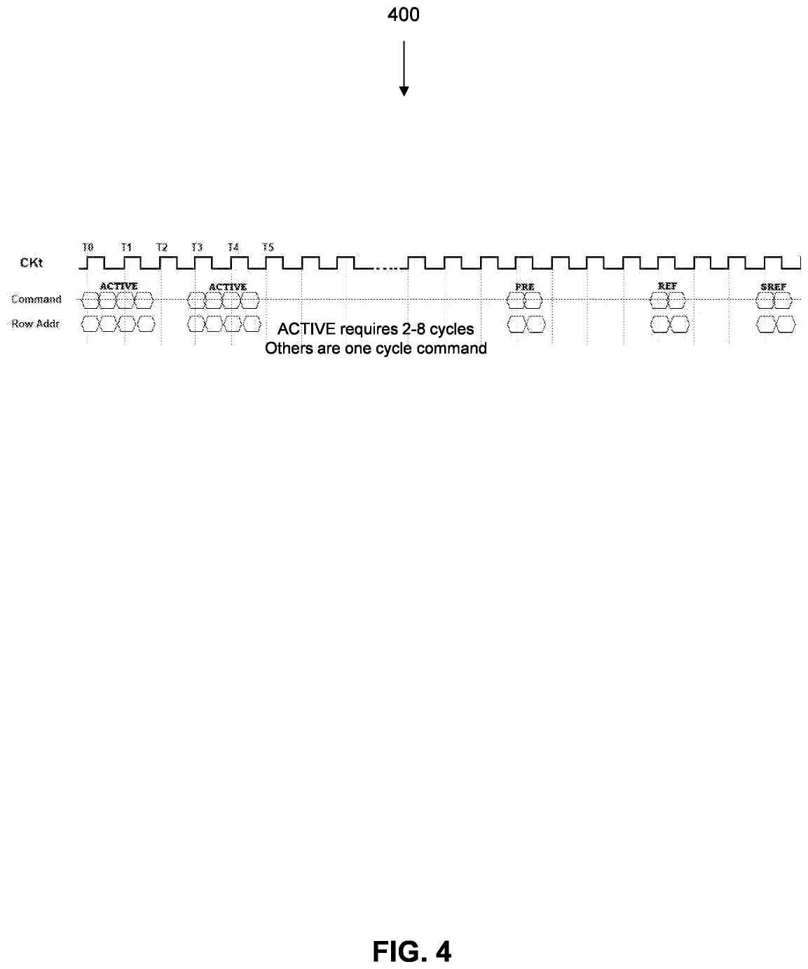

Referring now also to FIG. 4, exemplary timing diagram 400 illustrating activation of a memory page according to enhanced embodiments of the present disclosure is shown. For example, in timing diagram 400 activation of a plurality of sections of a memory page spread across memory banks is shown. In such embodiments, multiple row addresses for sections 210, 220 may be sent to bank(s) 205, 215 and the rows corresponding to the row addresses may be sensed so that requested data, such as requested from a host device 170, may be provided to the requesting device. In certain embodiments, such as embodiments with 8 sections for a memory page storing data, activation may take anywhere between 2-8 cycles to account for the possibility of up to 8 sections having the different row addresses being activated. The memory page may be activated as a whole, but instead of having to close the memory page to access data in different rows in different sections, the same memory page may be left open (i.e., activated), and data may be obtained from the different rows in the different sections without having to close the memory page to open a different memory page.

In certain embodiments, as indicated in the present disclosure, the memory hardware may be modified to accept a different address for each section of a memory page. The memory page may be still activated as a whole, hence taking advantage of simplicity, but the memory page data can come from different memory rows in each section 210, 220, or activation of some tiles (i.e., sections) can be disabled to save on power. In certain embodiments, providing such capability may be done by increasing the number of row address pins and increasing the tCK (e.g., test clock) frequency. As a result, the row address bandwidth may be increased orders of magnitude, such as 8×. Hence, all eight addresses per activate may be captured by memory hardware within the required time budget. In certain embodiments and using the preceding example, latches of the memory device 200, 102 may latch all eight row addresses during activation and hold them until after issuance of a precharge command, when the memory device 200, 102 uses them to write back the complex memory page. Thus, in certain embodiments, the precharge command at the protocol level may stay as usual. In certain embodiments, for linear 8 KB access (or other KB access) the interface of the memory device 102, 200 may have a cancellation logic (e.g., strobe signal or key word) that can notify the memory hardware to use first row address (or other specific row address) for all tiles or sections 210, 220.

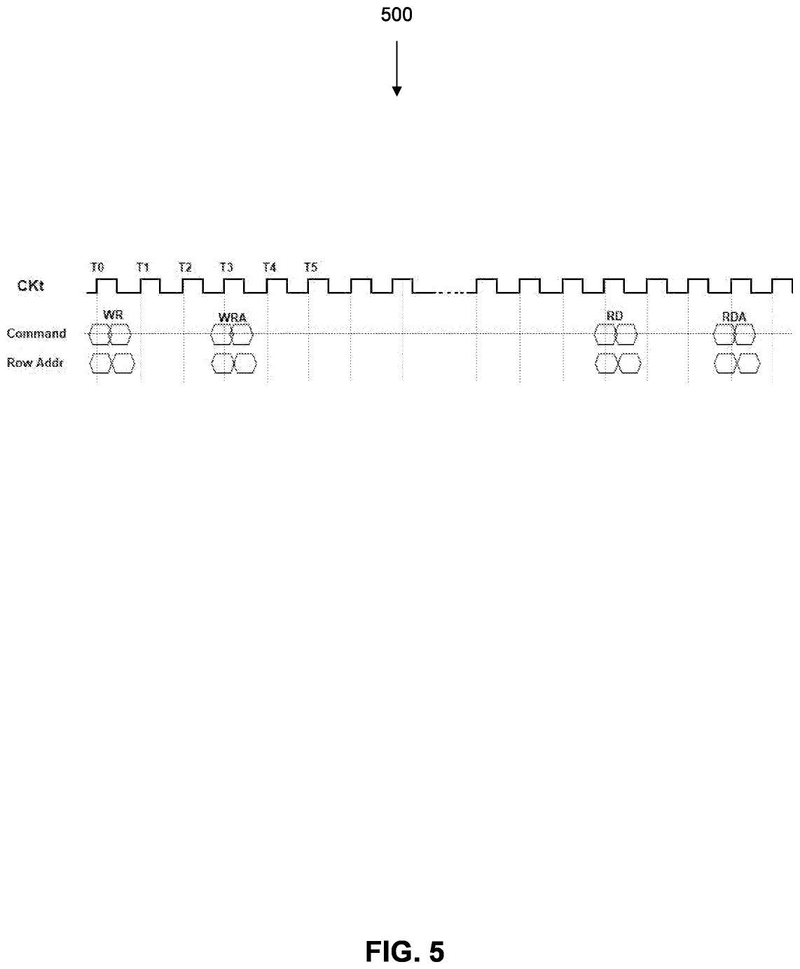

Referring now also to FIG. 5, an exemplary timing diagram 500 illustrating write and read commands issued during complex page access in a memory device (e.g., memory device 200, 102) according to embodiments of the present disclosure is shown. In diagram 500, for example, between activate and precharge commands, the read/write column commands may be issued at the memory interface because the complex memory page is latched in the latch(es) of the memory (e.g., in a memory page buffer), which is shared across tiles or sections. In certain embodiments, the memory controller may be configured to keep track of which columns belong to which memory tiles (or sections) and may schedule column accesses according to its algorithms. In certain embodiments, the memory controller may handle and orchestrate scheduling scenarios for optimal memory access using the described features.

In certain embodiments, the memory device 200, 102 may generate and store a programmable address map that allows the data to be spread among memory banks and tiles (i.e. sections). For example, tiles that belong to the same memory bank may be designated as a bank group. In certain embodiments, the memory interface may provide the memory controller with greater flexibility to compose a complex memory page and issue an activation for the memory page for random accesses. In certain embodiments, the controller can also coalesce (e.g., combine) memory requests belonging to the same linear row (e.g., 8K linear row) and issue a reduced activation for accesses that are spatially local. In certain embodiments, the controller may generate and maintain a priority queue in which the requests (e.g., 64B cacheline requests) are scheduled in the order of priority and the age (i.e., aged low priority requests become high priority). In certain embodiments, the features of the complex page formation may allow the controller to meet priority requirements for random accesses in a superior fashion when compared to a memory device without the features of the present disclosure. In certain embodiments, the memory controller may be configured to compose complex memory pages directly from the queue with potential speedup of up to 8× (or other magnitude) compared to other memory devices.

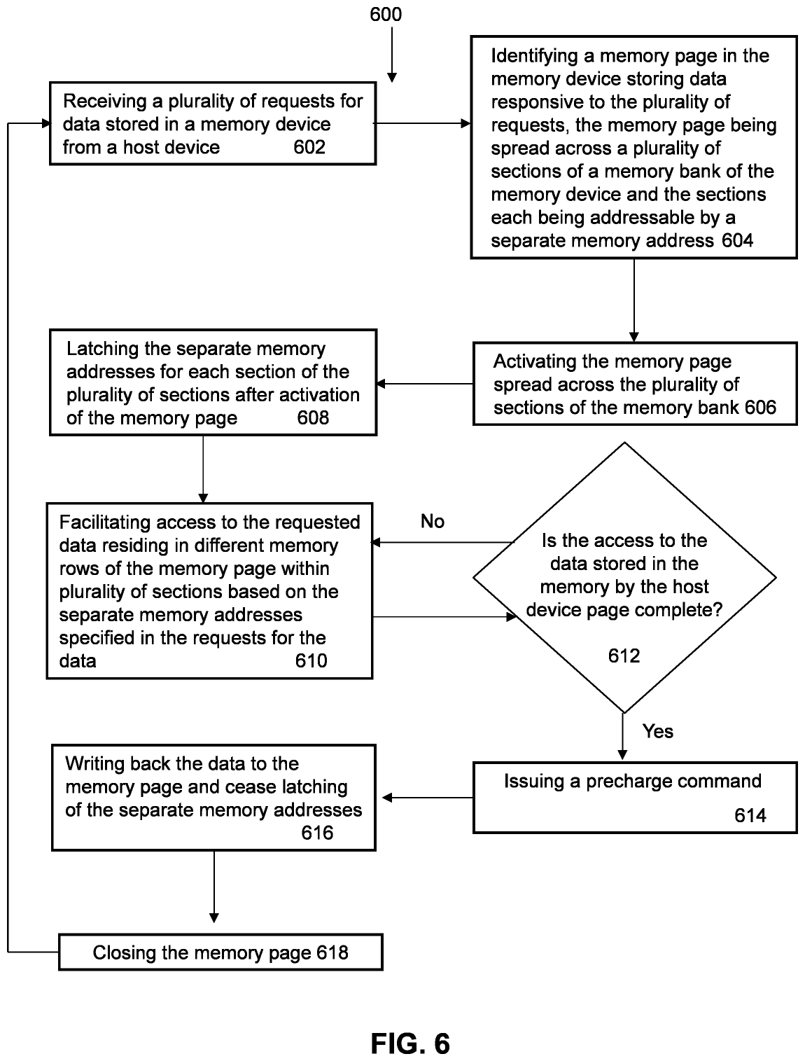

Referring now also to FIG. 6, FIG. 6 illustrates an exemplary method 600 for providing and/or facilitating complex memory page access in memory devices according to embodiments of the present disclosure. For example, the method of FIG. 6 can be implemented in the memory device 102 of FIG. 1 and/or any of the other systems, devices, and/or componentry illustrated in the Figures. In certain embodiments, the method of FIG. 6 can be performed by processing logic that can include hardware (e.g., processing device, circuitry, dedicated logic, programmable logic, microcode, hardware of a device, integrated circuit, deep learning accelerator, etc.), software (e.g., instructions run or executed on a processing device), or a combination thereof. In some embodiments, the method of FIG. 6 may be performed at least in part by one or more processing devices, memory devices, controllers, host devices, other systems, programs, and devices, or a combination thereof. Although shown in a particular sequence or order, unless otherwise specified, the order of the steps in the method 600 may be modified and/or changed depending on implementation and objectives. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In certain embodiments, the method 600 may include steps for providing complex memory page access in a memory device, such as, but not limited to, a hybrid-bonded memory device, high-bandwidth memory device, tightly-coupled memory device, or a combination thereof. Notably, the functionality provided by the method 600 provides memory page access using fewer memory resources, fewer computing resources, reduced time, greater convenience, and enhanced memory access versatility than other memory page access technologies. In certain embodiments, the method 600 may include, for example, steps for receiving requests for data stored in a memory device, determining where the requested data resides on a memory device (e.g., on a memory page of memory device 102), activating memory pages containing the requested data, latching memory addresses for each section of the activated memory page, facilitating access to the requested data from different rows of the memory page within a plurality of sections of a memory back based on the memory addresses, issuing precharge commands to close the memory pages, writing accessed data back to the memory page and cease latching of the memory addresses, closing the memory page, and then repeating the method as desired as new requests arrive. In certain embodiments, the method 600 may be performed by utilizing the system 100, the memory device 102, the host device 170, and/or by utilizing any combination of the componentry and any other systems and devices described herein or otherwise.

At step 602, the method 600 may include receiving a plurality of requests for data stored in a memory device (e.g., memory device 100). For example, the requests for data may be to access data necessary for a software process, provide data to a user requiring the data for some purpose, or a combination thereof. In certain embodiments, the data may be any type of data including, but not limited to, video content, image content, text content, metadata, augmented reality content, virtual reality content, audio content, information, any type of data, or a combination thereof. In certain embodiments, the request may include an identification of a row address and/or column address of a memory page of the memory device storing the data. In certain embodiments, the requests may include an identification of row addresses associated with separate sections of a memory page spread across separate sections of a memory bank of a memory device. In certain embodiments, the request may include an identity of the requesting device requesting the data (e.g., an identity of the host device 170), an indication of the type of data being requested, a size of the data, the location of the data, any other information, or a combination thereof. In certain embodiments, the requests for data may be issued by a device, such as host device 170, however, in certain embodiments, the request for data may be from another device, a software process, a memory controller 106 of the memory device 102, or a combination thereof. In certain embodiments, the requesting of the data may be performed and/or facilitated by utilizing the host device 170, the memory device 102, the memory controller 106, any other program, system, or device, or a combination thereof.

At step 604, the method 600 may include identifying a memory page in the memory device storing data responsive to the requests for data made by the host device(s). In certain embodiments, for example, the request for data may be for data stored in a particular memory page that is spread across a plurality of sections of a memory bank of a memory device. In certain embodiments, the sections of the memory page corresponding with the sections of the memory bank may be separately addressable with their own row addresses. In certain embodiments, the memory page as a whole may be addressable by its own row address as well. In certain embodiments, the identifying of the memory page containing the data responsive to the requests for data may be performed and/or facilitated by utilizing the host device 170, the memory device 102, the memory controller 106, any other program, system, or device, or a combination thereof.

At step 606, the method 600 may include activating the memory page spread across the plurality of sections of the memory bank. For example, the controller 106 and/or host device 170 may issue an activate command that opens the memory page and causes transfer of charge from capacitors of the memory device 102 to sense amplifiers of the memory device 102 so that the data bit values of the data bits stored in memory cells of the memory page may be accessed, modified, read, and/or determined. In certain embodiments, the activate command may be utilized to activate a subset of the sections of the memory page, however, in certain embodiments, the activate command may be utilized to activate the whole memory page. In certain embodiments, the activate command may be utilized to activate only the sections of the memory page containing data responsive to the requests. In certain embodiments, may leave certain sections deactivated to save on power utilized by the memory device 102. In certain embodiments, the activating of the memory page may be performed and/or facilitated by utilizing the host device 170, the memory device 102, the memory controller 106, any other program, system, or device, or a combination thereof.

At step 608, the method 600 may include latching the separate memory addresses and/or data stored in each section of the plurality of sections after activation of the memory page. In certain embodiments, the memory addresses and/or data may be latched in one or more latches of the memory device 102. In certain embodiments, the separate memory addresses and/or data may be latched so long as the memory page is activated, and, in certain embodiments, may no longer be latched when a precharge command is issued and/or the memory page is closed. In certain embodiments, the latching may be performed and/or facilitated by utilizing the memory device 102, the memory controller 106, any other program, system, or device, or a combination thereof. At step 610, the method 600 may include facilitating access to the requested data residing in different memory rows of the memory page within the plurality of sections based on the separate memory addresses (e.g., row addresses) specified in the requests for the data. In certain embodiments, for example, instead of having the capability to only access data at the same row in each section of the memory page, the method 600 may enable data to be accessed at different rows in each section of the memory page spread across the sections of the memory bank. In certain embodiments, the facilitating of the access to the requested data may be performed and/or facilitated by utilizing the host device 170, the memory device 102, the memory controller 106, any other program, system, or device, or a combination thereof.

At step 612, the method 600 may include determining if access to the data stored in the sections of the memory page by the host device (or other requesting device) is completed. For example, in certain embodiments, the determining may include determining whether the host device has accessed all the data stored in the memory page that has been requested, a threshold amount of data requested, if the host device has sent a signal indicating that the access is completed, or a combination thereof. In certain embodiments, the determination regarding whether the access is completed may be based on expiration of a certain amount of time or memory cycles. In certain embodiments, the determining may be performed and/or facilitated by utilizing the host device 170, the memory device 102, the memory controller 106, any other program, system, or device, or a combination thereof.

If, at step 612, it is determined that access to the data stored in the memory page has not yet completed, the method 600 may continue with step 610 until access to the memory page is completed. If, however, at step 612, it is determined that access to the data stored in the memory page has been completed, the method 600 may proceed to step 614. At step 614, the method 600 may include issuing a precharge command to close the memory page. In certain embodiments, for example, the precharge command may be utilized to deactivate the row(s) currently open in the memory bank associated with the memory page. In certain embodiments, the issuance of the precharge command may be performed and/or facilitated by utilizing the host device 170, the memory device 102, the memory controller 106, any other program, system, or device, or a combination thereof. At step 616, the method 600 may include writing back the data to the memory page and ceasing latching of the separate memory addresses (e.g., row addresses) that were latched when the activate command was issued. In certain embodiments, the memory device may restore the values read from the rows of capacitors of the memory bank by utilizing any number of sense amplifiers. Once the values are restored, the memory bank and page may be prepared for subsequent row accesses. In certain embodiments, the writing back of the data and/or the ceasing of the latching of the separate memory addresses may be performed and/or facilitated by utilizing the memory device 102, the memory controller 106, any other program, system, or device, or a combination thereof. At step 618, the method 600 may include closing the memory page. In certain embodiments, the closing of the memory page may be performed and/or facilitated by utilizing the host device 170, the memory device 102, the memory controller 106, any other program, system, or device, or a combination thereof. In certain embodiments, the method 600 may be repeated as desired and/or by the memory device 102, other components of the Figures, any system, a device, or a combination thereof. Notably, the method 600 may incorporate any of the other functionality as described herein and may be adapted to support the functionality of the present disclosure.

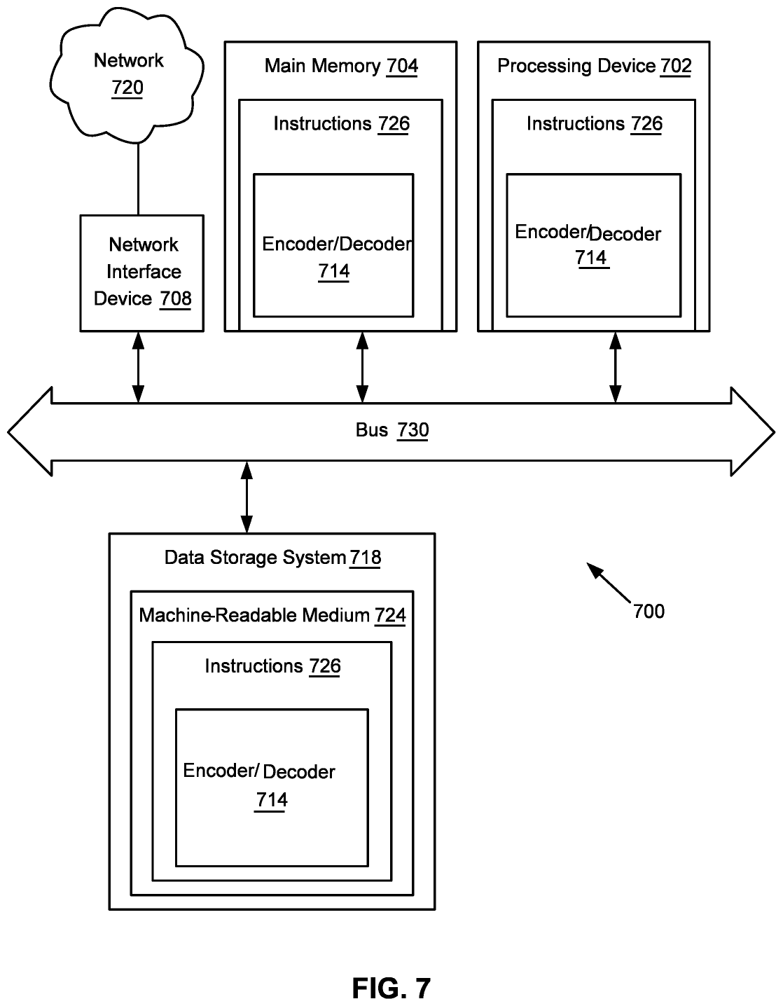

FIG. 7 illustrates an exemplary machine of a computer system 700 within which a set of instructions, for causing the machine to perform any one or more of the methodologies discussed herein, can be executed. In certain embodiments, the computer system 700 can correspond to a host system or device (e.g., a host device capable of communicating with the system 100, the memory device 102, the memory device 200, and/or other devices) that includes, is coupled to, or utilizes a memory system (e.g., the system 100 of FIG. 1). In certain embodiments, computer system 700 corresponds to system 100, the memory device 102, the memory device 200, the host device 170, and/or other devices or a combination thereof. In certain embodiments, the machine may be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment. In certain embodiments, the machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

In certain embodiments, the exemplary computer system 700 may include a processing device 702, a main memory 704 (e.g., read-only memory (ROM), flash memory, dynamic random-access memory (DRAM) such as synchronous DRAM (SDRAM) or Rambus DRAM (RDRAM), static random-access memory (SRAM), etc.), and/or a data storage system 718, which are configured to communicate with each other via a bus 730 (which can include multiple buses). In certain embodiments, processing device 702 may represent one or more general-purpose processing devices such as a microprocessor, a central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets, or processors implementing a combination of instruction sets. In certain embodiments, the processing device 802 may also be one or more special-purpose processing devices such as an application specific integrated circuit (ASIC), a field programmable gate array (FPGA), a digital signal processor (DSP), network processor, or the like.

The processing device 702 is configured to execute instructions 726 for performing the operations and steps discussed herein. For example, the processing device 702 may be configured to perform steps supporting the functionality provided by the system 100, the memory device 102, the memory device 200, the host device 170, other devices, any other componentry in the Figures, or a combination thereof. For example, in certain embodiments, the computer system 700 may be configured assist in requesting a write to the memory device 102, requesting a read of data stored in the memory device 102, requesting an erasure of data stored in the memory device 102, facilitating communications between the memory device 102 and the host device 170, performing any other operations as described herein, or a combination thereof. As another example, in certain embodiments, the computer system 700 may assist with conducting the operative functionality of the controller 106, the encoder 160, the decoder 162, the firmware 150, the memory device 200, the memory banks 114, 119, 124, the memory banks 129, 134, 139, or a combination thereof. In certain embodiments, computer system 700 may further include a network interface device 708 to communicate over a network 720.

The data storage system 718 can include a machine-readable storage medium 724 (also referred to as a computer-readable medium herein) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the system 100, the memory device 102, the memory device 200, or a combination thereof.

The illustrations of arrangements described herein are intended to provide a general understanding of the structure of various embodiments, and they are not intended to serve as a complete description of all the elements and features of apparatus and systems that might make use of the structures described herein. Other arrangements may be utilized and derived therefrom, such that structural and logical substitutions and changes may be made without departing from the scope of this disclosure. Figures are also merely representational and may not be drawn to scale. Certain proportions thereof may be exaggerated, while others may be minimized. Accordingly, the specification and drawings are to be regarded in an illustrative rather than a restrictive sense.

Thus, although specific arrangements have been illustrated and described herein, it should be appreciated that any arrangement calculated to achieve the same purpose may be substituted for the specific arrangement shown. This disclosure is intended to cover any and all adaptations or variations of various embodiments and arrangements of the invention. Combinations of the above arrangements, and other arrangements not specifically described herein, will be apparent to those of skill in the art upon reviewing the above description. Therefore, it is intended that the disclosure is not limited to the particular arrangement(s) disclosed as the best mode contemplated for carrying out this invention, but that the invention will include all embodiments and arrangements falling within the scope of the appended claims.

The foregoing is provided for purposes of illustrating, explaining, and describing embodiments of this invention. Modifications and adaptations to these embodiments will be apparent to those skilled in the art and may be made without departing from the scope or spirit of this invention. Upon reviewing the aforementioned embodiments, it would be evident to an artisan with ordinary skill in the art that said embodiments can be modified, reduced, or enhanced without departing from the scope and spirit of the claims described below.

What is claimed is:

1. A system, comprising:
a host device;
a memory device comprising:
a controller configured to:
receive, from the host device, a request for data stored in the memory device;
activate a memory page of the memory device storing the data associated with the request, wherein the memory page is spread across a plurality of sections of a memory bank of the memory device, wherein each section of the plurality of sections is configured to be accessible via a separate memory address of a plurality of memory addresses; and
facilitate access to portions of the data stored across the plurality of sections of the memory bank via the separate memory address for each section containing the portions of the data.

2. The system of claim 1, wherein the controller is further configured to latch the separate memory address for each section of the plurality of sections of the memory page after activation of the memory page.

3. The system of claim 2, wherein the controller is further configured to latch the separate memory address for each section of the plurality of sections within a time budget based on a clock frequency of the memory device.

4. The system of claim 1, wherein the controller is further configured to latch the separate memory address for each section of the plurality of sections until issuance of a precharge command for closing the memory page.

5. The system of claim 4, wherein the controller is further configured to write back the data latched by the memory device to the memory bank after issuance of the precharge command.

6. The system of claim 1, wherein the controller is further configured to utilize cancellation logic to utilize a first row address of the plurality of memory addresses for all sections of the memory bank to access the data.

7. The system of claim 6, wherein the controller is further configured to utilize a strobe, a keyword, or a combination thereof, for facilitating the cancellation logic.

8. The system of claim 1, wherein the controller is further configured to disable at least one section of the memory page to save power associated with the memory device.

9. The system of claim 1, wherein the controller is further configured to track which columns of the memory page belong to which section of the plurality of sections to schedule column accesses for the data.

10. The system of claim 1, wherein the controller is further configured to generate a programmable address map to facilitate spreading of the data among the sections, a plurality of memory banks including the memory bank, or a combination thereof.

11. The system of claim 1, wherein the controller is further configured to:
receive additional requests for the data stored in the memory device; and
coalesce a portion of the additional requests with the request belonging to a same linear row of the memory page to create a set of coalesced requests.

12. The system of claim 11, wherein the controller is further configured to issue a reduced activate command for accesses associated with the set of coalesced requests that are spatially local in the memory page.

13. The system of claim 1, wherein the controller is further configured to generate a priority queue including a plurality of requests including the request, wherein the plurality of requests are scheduled based on a priority associated with each request of the plurality of requests, an age of each request of the plurality of requests, or a combination thereof.

14. The system of claim 13, wherein the controller is configured to compose the memory page based on the priority queue.

15. A memory device, comprising:
a controller configured to:
generate a priority queue for a plurality of requests for data stored in the memory device, wherein the priority queue is generated based on an order of receipt of each request of the plurality of requests, an age of each request of the plurality of requests, or a combination thereof;
identify a memory page of the memory device storing the data for a portion of the plurality of requests;
issue an activate command to activate the memory page storing the data for the portion of the plurality of requests, wherein the memory page is spread across a plurality of sections of a memory bank of the memory device, wherein each section of the plurality of sections is accessible via a separate memory address of a plurality of memory addresses; and
enable access to portions of the data stored across the plurality of sections of the memory bank via the separate memory address for each section containing the portions of the data.

16. The memory device of claim 15, wherein the controller is further configured to adjust a test clock frequency of the memory device to increase a bandwidth associated with the plurality of memory addresses.

17. The memory device of claim 15, wherein the controller is further configured to close the memory page after the portions of the data stored across the plurality of sections of the memory bank are accessed.

18. The memory device of claim 15, wherein the controller is further configured to enable access to the portions of the data from different rows in the plurality of sections of the memory bank.

19. A method, comprising:
generating, at a memory device, a programmable address map to spread a memory page across a plurality of sections of a memory bank of the memory device, wherein each of the plurality of sections has a separate memory address that is stored in the programmable address map;
receiving, at the memory device, a plurality of requests for data;
activating a portion of the plurality of sections of the memory bank containing data in response to the plurality of requests while maintaining deactivation of a remaining portion of the plurality of sections of the memory bank not containing the data;
enabling, using the programmable address map, access to the data residing in different memory rows within the portion of the plurality of sections that have been activated.

20. The method of claim 19, further comprising latching the memory page in a page buffer that is shared across the plurality of sections of the memory bank.
